(19) United States
(12) Patent Application Publication
(10) Pub. No.: US 2009/0049357 A1
(43) Pub. Date: Feb. 19, 2009

(54) Decoding Method for Quasi-Cyclic Low-Density Parity-Check Codes and Decoder for The Same

(76) Inventors: Yeong-Luh Ueng, Hsin-Chu City (TW); Chung-Chao Cheng, Hsinchu (TW); Tsung Chieh Yang, Hsinchu City (TW)

Correspondence Address: HDSL, P.O. BOX 220746, CHANTILLY, VA, 20153-0746, US

(21) Appl. No.: 11/840,097

(22) Filed: Aug. 16, 2007

(51) Int. Cl. H03M 13/00

(52) U.S. Cl. 714/752

(57) ABSTRACT

A decoding method for quasi-cyclic low-density parity-check (QC-LDPC) codes sequentially decodes a plurality of block codes defined by an identical parity-check matrix derived from a parity-check matrix of the QC-LDPC codes, wherein size of the identical parity-check matrix is smaller than size of the parity-check matrix.

### BACKGROUND OF THE INVENTION

1. Field of Invention

The present invention relates to a decoding method and decoder for quasi-cyclic low-density parity-check (QC-LDPC) codes. More particularly, the present invention relates to a fast-convergence decoding method and memory-efficient decoder for QC-LDPC codes.

2. Description of Related Art

Low-density parity-check (LDPC) codes have attracted tremendous research interest recently because of their excellent error-correcting performance and their potential of highly parallel implementation of decoder. Although the Shannon limit can be achieved by irregular LDPC codes, the very large-scale integration (VLSI) implementation of an irregular LDPC decoder remains a big challenge. A practical design approach of LDPC coding system called Block-LDPC has been used to construct LDPC codes with effective VLSI implementation of decoder and good error-correcting performance. An LDPC code constructed by using Block-LDPC is indeed a quasi-cyclic (QC) LDPC code. The irregular LDPC codes selected by the standard of IEEE 802.16e (WiMax) are Block-LDPC codes.

Iterative message-passing decoding (MPD) based on sum-product algorithm (SPA) is a well-known decoding method for LDPC codes. However, for such a decoding method, a large number of iterations which cause low throughput are demanded to recover the reliable information.

The MPD for LDPC codes can be implemented by fully-parallel architecture, such as the one shown in FIG. 1, which results in a high throughput decoder but with complex interconnections caused by a quite large number of irregular edges (Each PU stands for a processing unit).

On the other hand, in order to reduce the interconnection complexity, a serial architecture is proposed as shown in FIG. 2. However, the shared processing units PU_{cn} and PUᵥₙ respectively computes all the rows or columns one after another and the throughput of the decoder based on serial architecture is low. In addition, two memory units (MU_{cn} and MUᵥₙ) are needed to store check-to-variable and variable-to-check messages.

To balance the complexity of interconnections and throughput, a partially-parallel architecture, where certain logic devices have to be utilized in a time-multiplexed manner, is used in several approaches, such as “Overlapped message passing for quasi-cyclic low-density parity check codes”, by Y. Chen and K. K. Parhi, IEEE Trans. Circuits Syst. I, Reg. Papers, vol. 51, no. 6, pp. 1106-1113, June 2004, “High-throughput LDPC decoders”, by M. M. Mansour and N. R. Shanbhag, IEEE Trans. VLSI System, vol. 11, no. 6, pp. 976-996, December 2003, and “Loosely coupled memory-based decoding architecture for low density parity check codes”, by S. H. Kang and I. C. Park, IEEE Trans. Circuit Syst. I, Reg. Papers, vol. 53, no. 5, pp. 1045-1056, May. 2006.

FIG. 3 is an architecture diagram of a conventional partially-parallel decoder. At the final Nᵢ decoding iteration, hard decisions of the code bits are produced by the processing unit PU_{hd}. Whereas the fully-parallel architecture computes all the messages simultaneously, the partially-parallel (or serial) architecture computes messages row-by-row or column-by-column because there is only a few number PU (or even only one PU) for each step. Therefore, variable messages calculated by a variable processing unit (PUᵥₙ) is stored into a memory and accessed later by a check processing unit (PU_{cn}). Accordingly, both the check-to-variable and variable-to-check messages have to be stored in the memory units MU_{cn} and MUᵥₙ, respectively.

The present invention proposes a partially-parallel architecture which is totally different from the above mentioned prior arts.

### SUMMARY OF THE INVENTION

One of the objects of the invention is to provide a decoding method for quasi-cyclic low-density parity-check (QC-LDPC) codes such that the throughput and the complexity can be balanced.

One of the objects of the invention is to provide a decoder for QC-LDPC codes such that the memory usage can be reduced.

To at least achieve the above and other objects, the invention provides a decoding method for quasi-cyclic low-density parity-check (QC-LDPC) codes. The decoding method sequentially decodes a plurality of block codes defined by an identical parity-check matrix derived from a parity-check matrix of the QC-LDPC codes, wherein each of the block codes is parallelly decoded with the identical parity-check matrix, and size of the identical parity-check matrix is smaller than size of the parity-check matrix.

In one embodiment of the present invention, the identical parity-check matrix is derived from the parity-check matrix by the steps of generating a temporary matrix by taking a plurality of selected rows of the parity-check matrix together, wherein every selected row is chosen from different block row of the parity-check matrix, and deleting all-zero columns of the temporary matrix to derive the identical parity-check matrix.

In one embodiment of the present invention, the identical parity-check matrix is derived from the parity-check matrix by the steps of generating a temporary matrix by taking a plurality of selected rows of the parity-check matrix together, wherein two neighbored selected rows in the temporary matrix are separated by a predetermined number of rows when they are in the parity-check matrix, and deleting all-zero columns of the temporary matrix to derive the identical parity-check matrix.

In one embodiment of the present invention, during a part of time when the decoder decodes the block codes, the decoder does not access an external memory but accesses local registers in a processing unit performing decoding of block codes to reduce bandwidth required for the external memory.

In one embodiment of the present invention, the step of sequentially decodes the block codes first indexes a plurality of code bits of the QC-LDPC code by a plurality of index sets such that one of the block codes can be obtained corresponding to one of the index sets, and then performs a plurality of global iterations on the block codes. Furthermore, each iteration comprising the steps of decoding a first one block code of the block codes with the identical parity-check matrix and a plurality of channel values of the code bits of the QC-LDPC code indexed by the index set corresponding to the first one block code, and sequentially decoding the following block codes by using the identical parity-check matrix, extrinsic information obtained by previously decoded block codes, and the index set corresponding to the decoding block code.

The present invention further provides a decoder for quasi-cyclic low-density parity-check codes, comprising a variable-node processing unit for receiving channel values and performing operations to generate variable-to-check messages, and a check-node processing unit for receiving the variable-to-check messages and performing operations to generate check-to-variable messages, which is characterized in not storing the variable-to-check messages but the check-to-variable messages in a memory unit.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an architecture diagram of a conventional fully-parallel decoder.

FIG. 2 is an architecture diagram of a conventional serial decoder.

FIG. 3 is an architecture diagram of a conventional partially-parallel decoder.

FIG. 4 is a block-type parity-check matrix of LDPC codes with rate ½ in the IEEE 802.16e standards.

FIG. 5 is a flow chart of decoding method in accordance to one embodiment of the present invention.

FIG. 6 is a flow chart of deriving the identical parity-check matrix Hₗ in accordance to one embodiment of the present invention.

FIG. 7 is a flow chart of the sequential decoding procedure of the decoding method in accordance to one embodiment of the present invention.

FIG. 8 is a block diagram of a decoder in accordance to one embodiment of the present invention.

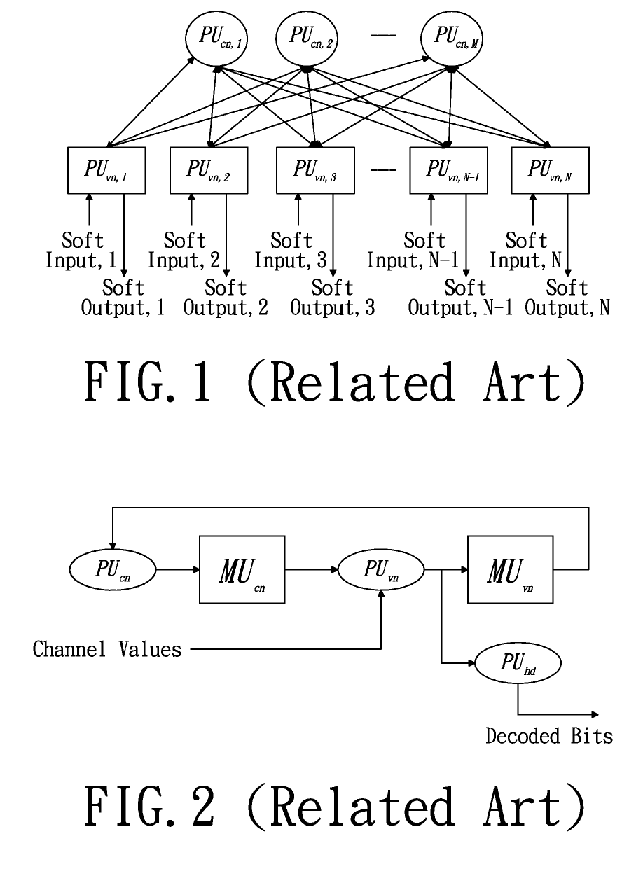

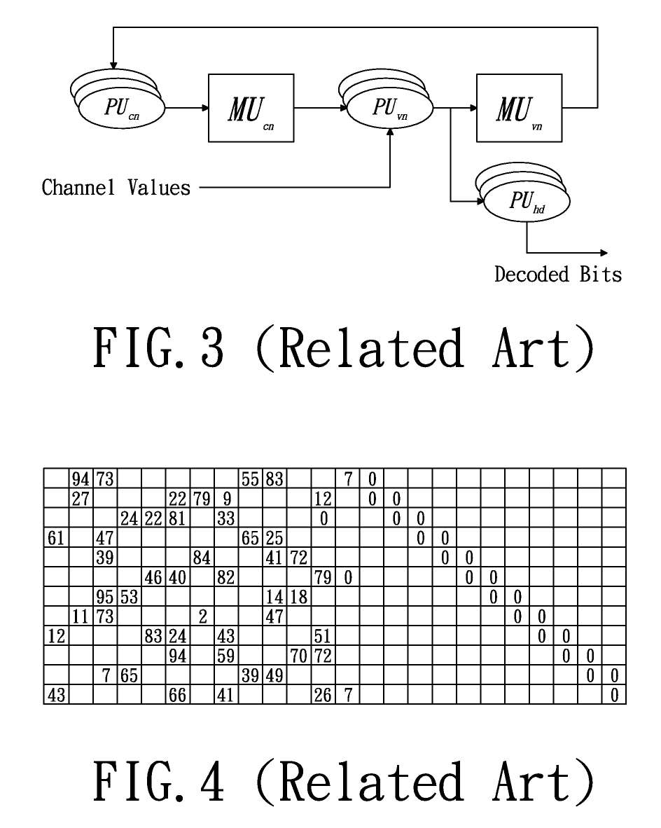

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

First of all, the parity-check matrix H of Block-LDPC (QC-LDPC) code C used in the IEEE 802.16e standards is briefly reviewed. The M×N parity check matrix H is constructed based on an M_{b}×N_{b} base parity check matrix H_{b}, where M=zM_{b}, N=zN_{b}, and z is a positive integer. In matrix H_{b}, each 0 is replaced by a z×z zero sub-matrix and each 1 at the position (i, j) is replaced by a z×z sub-matrix that is obtained by right cyclic shifting a z×z identity matrix by p(i, j) columns, where p(i, j)≧0, 0≦i≦(M_{b}−1), 0≦j≦N_{b}−1. The matrix H_{b} and p(i, j) can be found in the IEEE 802.16e standards. For the (2304,1152) LDPC code, M=1152, N=2304, z=96, M_{b}=12, N_{b}=24. FIG. 4 shows a block-type parity-check matrix H of LDPC codes with rate ½ in the IEEE 802.16e standards. In the matrix, each of the elements (i,j) represents an z×z sub-matrix and a row of the matrix is a block row of the parity check matrix H.

For message-passing decoding (MPD) based on sum-product algorithm (SPA), let λj=ln(Pr(vⱼ=0|yⱼ)/Pr(vⱼ=1|yⱼ)) be the channel value of bit (variable node) vⱼ, where yⱼ is the noise-corrupted form of vⱼ. Let Rᵢⱼ[k] be the check-to-variable message (i.e. extrinsic value) from check node i to variable node j at iteration k, Qᵢⱼ[k] be the variable-to-check message from variable node i to check node j at iteration k, R[i] be the index set of variable nodes involving check node i, and C[j] be the index set of check nodes involving variable node j.

At initialization: For k=0, the check-to-variable messages Rᵢⱼ[0] from the ith check node to the jth variable node are initialized to zero for all i, with jεR[i].

At iteration k:
1. Operations at variable nodes: For each variable node j, compute Qⱼᵢ[k] corresponding to each of its check node neighbors i according to

$${Q}_{ji} [ k ] = {λ}_{j} + {\sum }_{{i}^{′} ∈ C [ j ] \backslash \{ i \}} {R}_{{i}^{′} j} [ k - 1 ] \qquad ( 1 )$$

2. Operations at check nodes: For each check node i, compute Rᵢⱼ[k] corresponding to each of its variable node neighbors j according to

$${R}_{ij} [ k ] = - {S}_{ij} [ k ] ( ψ ( \vert {\sum }_{{j}^{′} ∈ R [ i ] \backslash \{ j \}} ψ ( \vert {Q}_{{j}^{′} i} [ k ] \vert ) \vert ) \\ where ψ ( \vert x \vert ) = ln ( \vert \frac{exp ( x ) - 1}{exp ( x ) + 1} \vert ) , \\ and {S}_{ij} [ k ] = {\prod }_{{j}^{′} ∈ R [ i ] \backslash \{ j \}} Sign ( {Q}_{{j}^{′} i} [ k ] ) . \qquad ( 2 )$$

Hard decision:
At iteration Nᵢ, for each variable node j, compute the a posterior reliability value Aⱼ according to

$${Λ}_{j} = {λ}_{j} + {\sum }_{i ∈ C [ j ]} {R}_{ij} [ Ni ] \qquad ( 3 )$$

Hard decisions are then made based on the sign of Aⱼ, j=0, 1, . . . , N−1.

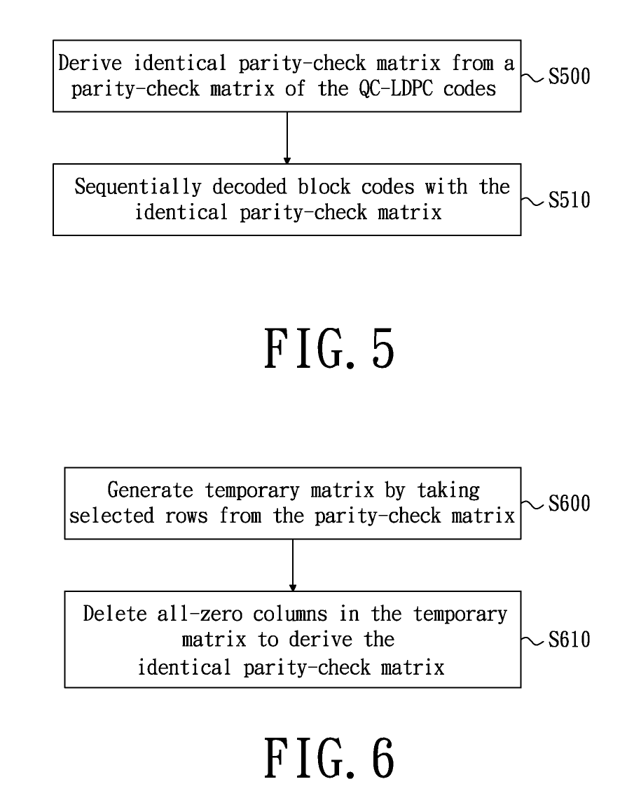

Now refer to FIG. 5, which is a flow chart of decoding method in accordance to one embodiment of the present invention. In the embodiment, an identical parity-check matrix Hₗ is derived from a parity-check matrix H of the QC-LDPC codes (Step 500). After that, the identical parity-check matrix Hₗ is used to decode each of a plurality of block codes Cᵢ(0), Cᵢ(1) . . . Cᵢ(z−1) sequentially (Step 510), wherein each of the block codes Cᵢ(0), Cᵢ(1) . . . Cᵢ(z−1) can be decoded parallelly.

More specifically, refer to FIG. 6, which is a flow chart of deriving the identical parity-check matrix Hₗ in accordance to one embodiment of the present invention, for i=0, 1, . . . , z−1, let a temporary matrix Hₗ(i) be an M_{b}×N matrix which contains the i-th, (i+z)-th, (i+2z)-th, . . . , and (i+(M_{b}−1)z)-th rows of the parity-check matrix H (Step 600). For i=0, 1, . . . , z−1, let Sₗ(i) be an index set which indicates the non-zero columns of Hₗ(i). For example, if only the first, the second, and the third columns of temporary matrix Hₗ(0) are non-zero, then Sₗ(0)={1, 2, 3}. For i=0, 1, . . . , z−1, let Hₗ(i) be an M_{b}×Nₗ matrix which is obtained by deleting the all-zero columns of temporary matrix Hₗ′(i) and we have |Sₗ(i)|=Nᵢ (Step 610). From the quasi-cyclic structure of the parity-check matrix H, the matrices Hₗ(i), i=0, 1, 2, . . . , z−1 are identical to the identical parity-check matrix Hₗ and Sᵢ(i+1)=∪ⱼ₌₀^{N}^{_{b}}⁻¹{q|q−jz=(k+1−jz)mod z; jz ≦k<(j+1)z, kεSₗ(i)}, i=0, 1, . . . , z−2. In addition, sets Sₗ(i), i=0, 1, . . . , z−1, are not the same and Sᵢ(i)∩(∪_{j=0,j≠i}^{z-1}Sₗ(j))≠φ for i=0, 1, . . . , z−1, where φ is the null set. Notably, Nₗ is not equal to N_{b} and Nₗ is much smaller than N.

It should be noted that, in another approach, the selected rows are chosen from the block rows of the parity-check matrix such that a block row corresponding to one of the selected rows is different from block rows corresponding to other selected rows. In other words, there is only one row to be selected from a block row of the parity-check matrix. It is not important that which row of the block row is selected.

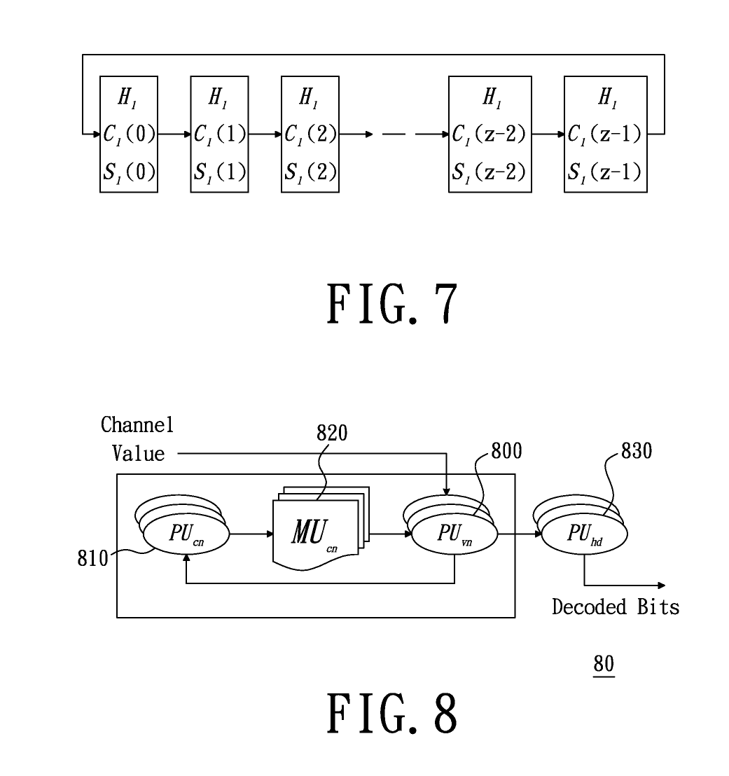

The code bits of QC-LDPC code C indexed by Sₗ(i) form a linear block code Cₗ(i), i=0, 1, . . . , z−1. We can find that the M_{b}×Nₗ matrix Hₗ(i), or equally, the identical parity-check matrix Hₗ, is the parity-check matrix of Cₗ(i), i=0, 1, . . . , z−1. Refer to FIG. 7, which is a flow chart of the sequential decoding procedure of the decoding method in accordance to one embodiment of the present invention. The decoding of QC-LDPC code C is implemented by sequentially decoding block codes Cₗ(0), Cₗ(1) . . . Cₗ(z−1). The codewords of each of the block codes Cₗ(0), Cₗ(1) . . . Cₗ(z−1) is obtained from indexing the code bits of C by Sₗ(0), Sₗ(1), . . . , Sₗ(z−1), respectively. The block code Cₗ(0) is firstly decoded by using the channel values of code bits of C indexed by Sₗ(0). After that, the block code Cₗ(1) is decoded by using the channel values of code bits of QC-LDPC code C indexed by Sₗ(1) and the extrinsic information provided by the decoding of block code Cₗ(0). Other block codes Cₗ(i), i=2, 3, . . . , z−1, are decoded by the same method. Such one-round decoding of Cₗ(i), i=0, 1, . . . , z−1, is called a global iteration for the decoding of QC-LDPC code C. After decoding block code Cₗ(z−1), another global iteration for the decoding of QC-LDPC code C is performed again.

We can use the MPD based on SPA with Nₗₒ iterations to decode block codes Cₗ(i), i=0, 1, . . . , z−1. For each iteration to decode block code Cₗ(i), in one embodiment, the above mentioned channel values or extrinsic information can be stored in the registers in the processing unit which performs the decoding of the block code Cₗ(i). Accordingly, bandwidth required for accessing external memory, such as an SRAM or register file, can be effectively reduced, and therefore clock timing of the SRAM (or register file) can be reduced or a single port SRAM can be used to replace a dual port SRAM.

Since Sₗ(i)∪(∩_{j=0,j≠i}^{z-1}Sₗ(j))≠φ for i=0, 1, . . . , z−1, the decoding of block code Cₗ(i) can use the extrinsic information provided by the decoding of other block codes Cₗ(j), j≠i. Since in the decoding of Cₗ(i), we can use extrinsic information provided by the decoding of other block codes Cₗ(j) j≠i, within the same global iteration, the speed of convergence is faster than that of the conventional iterative MPD.

FIG. 8 shows a block diagram of a decoder in accordance to one embodiment of the present invention. In the embodiment, decoder 80 includes a plurality of variable-node processing units 800 for receiving channel values of block codes Cₗ(i) and performing operations to generate variable-to-check messages, a plurality of check-node processing units 810 for receiving the variable-to-check messages and performing operations to generate check-to-variable messages, a plurality of hard-decision processing units 830, and at least one memory unit 820 for storing the check-to-variable messages.

The quantized log-likelihood ratios (channel values) of the received code bits are fed into the decoder 80. The processing units 800 and 810 perform the operations at check nodes and variable nodes, respectively, for identical parity-check matrix Hₗ. The detail architectures and the associated quantization parameters of processing units 800 and 810 can be find in “Memory-efficient decoding of LDPC codes”, in Proc. ISIT, September 2005, pp. 459-463, by Lee, J. K.-S. and Thorpe, J., which is incorporated here for reference. The memory unit 820 is used to store the check-to-variable message. At the final global iteration, the hard decisions of the code bits are produced by the hard-decision processing unit 830. Note that the hardware complexities of processing units 800 and 810 are proportional to Nₗ instead of N.

For the (2304, 1152) LDPC code in the IEEE 802.16e standard, Nₗ=63 and N=2304. If we use a fully-parallel architecture to implement the decoder of block code Cₗ(i), we can achieve higher throughput as compared to the pure serial architecture. In addition, the improved convergence speed can further increase the throughput. As compared to the serial architecture, we do not need memory to store variable-to-check message. As compare to the fully-parallel architecture, we do not have complex interconnections since the code length of block code Cₗ(i) is much less than that of QC-LDPC code C.

The proposed decoding method has improved convergence speed for the LDPC code. Based on the decoding method, the decoder is memory efficient since only check-to-variable messages (i.e., extrinsic value) are stored.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A decoding method for quasi-cyclic low-density parity-check (QC-LDPC) codes, which is characterized in sequentially decoding a plurality of block codes defined by an identical parity-check matrix derived from a parity-check matrix of the QC-LDPC codes, wherein size of the identical parity-check matrix is smaller than size of the parity-check matrix.

2. The decoding method of claim 1, wherein the identical parity-check matrix is derived from the parity-check matrix by the steps of:
generating a temporary matrix by taking a plurality of selected rows of the parity-check matrix together, wherein every selected row is chosen from different block row of the parity-check matrix; and
deleting all-zero columns of the temporary matrix to derive the identical parity-check matrix.

3. The decoding method of claim 1, wherein the identical parity-check matrix is derived from the parity-check matrix by the steps of:
generating a temporary matrix by taking a plurality of selected rows of the parity-check matrix together, wherein two neighbored selected rows in the temporary matrix are separated by a predetermined number of rows when they are in the parity-check matrix; and
deleting all-zero columns of the temporary matrix to derive the identical parity-check matrix.

4. The decoding method of claim 3, wherein sequentially decoding the block codes comprising the steps of:
indexing a plurality of code bits of the QC-LDPC code by a plurality of index sets to obtain the code words of the block codes such that one of the block codes is corresponding to one of the index sets; and
performing a plurality of global iterations on the block codes, wherein each global iteration comprising the steps:
decoding a first one block code of the block codes with the identical parity-check matrix and a plurality of channel values of the code bits of the QC-LDPC code indexed by the index set corresponding to the first one block code; and
sequentially decoding the following block codes by using the identical parity-check matrix, extrinsic information obtained by previously decoded block codes, and the index set corresponding to the currently decoded block code.

5. The decoding method of claim 4, wherein during a part of time when the decoder decodes the block codes, the decoder does not access an external memory but accesses local registers in a processing unit performing decoding of block codes to reduce bandwidth required for the external memory.

6. The decoding method of claim 2, wherein sequentially decoding the block codes comprising the steps of:
indexing a plurality of code bits of the QC-LDPC code by a plurality of index sets to obtain the code words of the block codes such that one of the block codes is corresponding to one of the index sets; and
performing a plurality of global iterations on the block codes, wherein each global iteration comprising the steps:
decoding a first one block code of the block codes with the identical parity-check matrix and a plurality of channel values of the code bits of the QC-LDPC code indexed by the index set corresponding to the first one block code; and
sequentially decoding the following block codes by using the identical parity-check matrix, extrinsic information obtained by previously decoded block codes, and the index set corresponding to the currently decoded block code.

7. A decoder for quasi-cyclic low-density parity-check codes, comprising a plurality of variable-node processing units for receiving channel values and performing operations to generate variable-to-check messages, and a plurality of check-node processing units for receiving the variable-to-check messages and performing operations to generate check-to-variable messages, which is characterized in not storing the variable-to-check messages but the check-to-variable messages in a memory unit.
